(19) United States
(12) Patent Application Publication
(10) Pub. No.: US 2024/0235494 A1
(43) Pub. Date: Jul. 11, 2024

(54) DYNAMIC BANDWIDTH OPTIMIZATION FOR OPERATIONAL AMPLIFIERS

(71) Applicant: Atmosic Technologies, Inc., Campbell, CA (US)

(72) Inventors: Bita Nezamfar, Los Altos, CA (US); Manolis Terrovitis, Athens (GR); Justin Ann-Ping Hwang, Sunnyvale, CA (US)

(73) Assignee: Atmosic Technologies, Inc., Campbell, CA (US)

(21) Appl. No.: 18/404,711

(22) Filed: Jan. 4, 2024

Related U.S. Application Data
(60) Provisional application No. 63/437,266, filed on Jan. 5, 2023.

(51) Int. Cl. H03F 1/42; H03F 3/45

(52) U.S. Cl. CPC H03F 1/42; H03F 3/45475; H03F 2200/129; H03F 2200/36

(57) ABSTRACT

This disclosure provides methods, devices, and systems for operational amplifier frequency compensation. The present implementations more specifically relate to techniques for dynamically calibrating the capacitance of a compensation capacitor based on the frequency at which an operational amplifier oscillates. In some aspects, an operational amplifier may include a differential input stage, a high gain stage, and a frequency compensation controller configured to operate the operational amplifier in a normal mode or a calibration mode. Compensation capacitors are switchably coupled between the outputs of the differential input stage and the outputs of the high gain stage based on the operating mode of the operational amplifier. More specifically, in the calibration mode, the coupling of the capacitors causes an output voltage of the op amp to oscillate relative to an input voltage. By contrast, in the normal mode, the coupling of the capacitors causes the output voltage to track the input voltage.

### CROSS-REFERENCE TO RELATED APPLICATION

This application claims priority and benefit under 35 USC § 119(e) to U.S. Provisional Patent Application No. 63/437,266, filed on Jan. 5, 2023, which is incorporated herein by reference in its entirety.

### TECHNICAL FIELD

The present implementations relate generally to operational amplifiers (op amps), and specifically to dynamic bandwidth optimization techniques for op amps.

### BACKGROUND OF RELATED ART

Operational amplifiers (“op amps”) are analog circuit components designed to amplify signals (such as voltages or currents) by a gain factor (A). The gain of an op amp varies based on the frequency of the input signal. For example, an op amp's frequency response curve (or Bode plot) is generally flat or constant from direct current (DC) to a threshold frequency (also referred to as a “pole”), beyond which the gain falls (initially) at a rate of 20 dB/decade. Poles may be caused by capacitive loading or parasitic capacitances in the op amp (such as between the various stages of a multi-stage op amp). Each pole introduces a 90° phase shift between the input signal and the output signal and results in a 20 dB/decade increase in the rate at which the gain of the op amp falls. As a result, the op amp will oscillate if the frequency of the input signal is greater than a second pole on the frequency response curve (due to a 180° phase shift between the input signal and the output signal).

Frequency compensation techniques may improve the stability of an op amp. For example, a compensation capacitor (coupled in feedback between the input and output terminals of an op amp) can be used to introduce additional capacitance to the first pole of the op amp, thereby increasing the frequency separation between the first and second poles in the frequency response curve so that the op amp reaches unity gain (0 dB) before the input and output signals are shifted 180° out of phase. This phenomenon is often referred to as “pole splitting” or the “Miller effect.” Pole splitting simultaneously raises the frequency of the second pole and lowers the frequency of the first pole. In other words, the compensation capacitor may improve the stability of the op amp at the cost of op amp bandwidth. To achieve optimal performance (or gain) of the op amp over the widest possible range of frequencies, the compensation capacitor should provide the smallest phase margin (equal to 180° minus the phase at unity gain) that avoids oscillation.

Process variations may cause the bandwidth of an op amp to deviate from a target or specified bandwidth. Extreme or worst-case process variations are often referred to as process “corners.” To ensure the stability of any op amp fabricated using a given process, the compensation capacitors associated with existing frequency compensation techniques are often designed to guarantee adequate phase margin (such as 45° or 60°) at the process corners. However, due to process variations, the resulting phase margin may be significantly larger when the same compensation capacitors are applied to some op amps manufactured using the same process. As such, existing frequency compensation techniques often result in overcompensation, which may unnecessarily reduce the bandwidths of some op amps. Thus, there is a need to improve the stability of op amps over process corners without unduly limiting the bandwidths of the op amps.

### SUMMARY

This Summary is provided to introduce in a simplified form a selection of concepts that are further described below in the Detailed Description. This Summary is not intended to identify key features or essential features of the claimed subject matter, nor is it intended to limit the scope of the claimed subject matter.

One innovative aspect of the subject matter of this disclosure can be implemented in a multi-stage operational amplifier (op amp) including a first amplifier stage, a second amplifier stage, a controller, a first compensation capacitor, and a second compensation capacitor. The first amplifier stage, which has a pair of first and second input terminals and a pair of first and second output terminals, is configured to produce a first differential voltage across the first and second output terminals based on a voltage difference between the first and second input terminals. The second amplifier stage, which has a pair of third and fourth output terminals and a pair of third and fourth input terminals coupled to the first and second output terminals, respectively, of the first amplifier stage, is configured to produce a second differential voltage between the third and fourth output terminals based on the first differential voltage. The controller is configured to operate the multi-stage op amp in a normal mode or a calibration mode. The first compensation capacitor has a first terminal coupled to the third output terminal of the second amplifier stage and a second terminal switchably coupled to one of the first or second output terminals of the first amplifier stage based on whether the multi-stage op amp operates in the normal mode or the calibration mode. The second compensation capacitor has a first terminal coupled to the fourth output terminal of the second amplifier stage and a second terminal switchably coupled to one of the first or second output terminals of the first amplifier stage based on whether the multi-stage op amp operates in the normal mode or the calibration mode.

Another innovative aspect of the subject matter of this disclosure can be implemented in a method performed by a controller for a multi-stage op amp. The method includes steps of configuring the multi-stage op amp to operate in a calibration mode so that the multi-stage op amp produces a first output voltage that oscillates in response to an input voltage received by the multi-stage op amp; tuning a capacitance or current associated with the multi-stage op amp so that the first output voltage oscillates at a target frequency when the multi-stage op amp is configured to operate in the calibration mode; and configuring the multi-stage op amp to operate in a normal mode so that the multi-stage op amp produces a second output voltage that tracks the input voltage based on the tuned capacitance or current.

Another innovative aspect of the subject matter of this disclosure can be implemented in a controller for a multi-stage op amp including a processing system and a memory. The memory stores instructions that, when executed by the processing system, causes the controller to configure the multi-stage op amp to operate in a calibration mode so that the multi-stage op amp produces a first output voltage that oscillates in response to an input voltage received by the multi-stage op amp; tune a capacitance or current associated with the multi-stage op amp so that the first output voltage oscillates at a target frequency when the multi-stage op amp is configured to operate in the calibration mode; and configure the multi-stage op amp to operate in a normal mode so that the multi-stage op amp produces a second output voltage that tracks the input voltage based on the tuned capacitance or current.

### BRIEF DESCRIPTION OF THE DRAWINGS

The present implementations are illustrated by way of example and are not intended to be limited by the figures of the accompanying drawings.

FIG. 1 shows an example amplifier circuit based on an operational amplifier (op amp).

FIG. 2 shows an example multi-stage op amp capable of dynamic frequency compensation, according to some implementations.

FIG. 3A shows a circuit diagram of an example multi-stage op amp configured in a normal operating mode.

FIG. 3B shows a circuit diagram of an example multi-stage op amp configured in a calibration mode, according to some implementations.

FIG. 4 shows a block diagram of an example frequency compensation controller, according to some implementations.

FIG. 5 shows an illustrative flowchart depicting an example operation for tuning a multi-stage op amp, according to some implementations.

### DETAILED DESCRIPTION

In the following description, numerous specific details are set forth such as examples of specific components, circuits, and processes to provide a thorough understanding of the present disclosure. The term “coupled” as used herein means connected directly to or connected through one or more intervening components or circuits. The terms “computer system,” “electronic system,” and “electronic device” may be used interchangeably to refer to any system capable of electronically processing information. Also, in the following description and for purposes of explanation, specific nomenclature is set forth to provide a thorough understanding of the aspects of the disclosure. However, it will be apparent to one skilled in the art that these specific details may not be required to practice the example embodiments. In other instances, well-known circuits and devices are shown in block diagram form to avoid obscuring the present disclosure. Some portions of the detailed descriptions which follow are presented in terms of procedures, logic blocks, processing and other symbolic representations of operations on data bits within a computer memory.

These descriptions and representations are the means used by those skilled in the data processing arts to most effectively convey the substance of their work to others skilled in the art. In the present disclosure, a procedure, logic block, process, or the like, is conceived to be a self-consistent sequence of steps or instructions leading to a desired result. The steps are those requiring physical manipulations of physical quantities. Usually, although not necessarily, these quantities take the form of electrical or magnetic signals capable of being stored, transferred, combined, compared, and otherwise manipulated in a computer system. It should be borne in mind, however, that all of these and similar terms are to be associated with the appropriate physical quantities and are merely convenient labels applied to these quantities.

Unless specifically stated otherwise as apparent from the following discussions, it is appreciated that throughout the present application, discussions utilizing the terms such as “accessing,” “receiving,” “sending,” “using,” “selecting,” “determining,” “normalizing,” “multiplying,” “averaging,” “monitoring,” “comparing,” “applying,” “updating,” “measuring,” “deriving” or the like, refer to the actions and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

In the figures, a single block may be described as performing a function or functions; however, in actual practice, the function or functions performed by that block may be performed in a single component or across multiple components, and/or may be performed using hardware, using software, or using a combination of hardware and software. To clearly illustrate this interchangeability of hardware and software, various illustrative components, blocks, modules, circuits, and steps have been described below generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure. Also, the example input devices may include components other than those shown, including well-known components such as a processor, memory and the like.

The techniques described herein may be implemented in hardware, software, firmware, or any combination thereof, unless specifically described as being implemented in a specific manner. Any features described as modules or components may also be implemented together in an integrated logic device or separately as discrete but interoperable logic devices. If implemented in software, the techniques may be realized at least in part by a non-transitory processor-readable storage medium including instructions that, when executed, performs one or more of the methods described above. The non-transitory processor-readable data storage medium may form part of a computer program product, which may include packaging materials.

The non-transitory processor-readable storage medium may comprise random access memory (RAM) such as synchronous dynamic random-access memory (SDRAM), read only memory (ROM), non-volatile random access memory (NVRAM), electrically erasable programmable read-only memory (EEPROM), FLASH memory, other known storage media, and the like. The techniques additionally, or alternatively, may be realized at least in part by a processor-readable communication medium that carries or communicates code in the form of instructions or data structures and that can be accessed, read, and/or executed by a computer or other processor.

The various illustrative logical blocks, modules, circuits and instructions described in connection with the embodiments disclosed herein may be executed by one or more processors (or a processing system). The term “processor,” as used herein may refer to any general-purpose processor, special-purpose processor, conventional processor, controller, microcontroller, and/or state machine capable of executing scripts or instructions of one or more software programs stored in memory.

As described above, operational amplifiers (“op amps”) are analog circuit components designed to amplify signals (such as voltages or currents) by a gain factor (A). The gain of an op amp varies based on the frequency of the input signal. For example, an op amp's frequency response curve is generally flat or constant from direct current (DC) to a threshold frequency (also referred to as a “pole”), beyond which the gain falls (initially) at a rate of 20 dB/decade. Poles may be caused by capacitive loading or parasitic capacitances in the op amp (such as between the various stages of a multi-stage op amp). Each pole introduces a 90° phase shift between the input signal and the output signal and results in an additional 20 dB/decade increase in the rate at which the gain of the op amp falls. As a result, the op amp will oscillate if the frequency of the input signal is greater than a second pole on the frequency response curve (due to a 180° phase shift between the input signal and the output signal).

Frequency compensation is a technique for improving the stability of an op amp. For example, a compensation capacitor (coupled in feedback between the input and output terminals of an op amp) can be used to introduce additional capacitance to the first pole, thereby increasing the frequency separation between the first pole and the second pole so that the gain of the op amp reaches unity (0 dB) before the op amp introduces a 180° phase shift. This phenomenon is often referred to as “pole splitting” or the “Miller effect.” Pole splitting simultaneously raises the frequency of the second pole and lowers the frequency of the first pole. In other words, the compensation capacitor may improve the stability of the op amp at the cost of op amp bandwidth. To achieve optimal performance (or gain) of the op amp over the widest possible range of frequencies, the compensation capacitor should provide the smallest phase margin (equal to 180° minus the phase at unity gain) that avoids oscillation.

Process variations may cause the bandwidth of an op amp to deviate from a target or specified bandwidth. Extreme or worst-case process variations are often referred to as process “corners.” To ensure the stability of any op amp fabricated using a given process, the compensation capacitors associated with existing frequency compensation techniques are often designed to guarantee adequate phase margin (such as 45° or 60°) at the process corners. However, due to process variations, the resulting phase margin may be significantly larger when the same compensation capacitors are applied to some op amps manufactured using the same process. As such, existing frequency compensation techniques often result in overcompensation, which may unnecessarily reduce the bandwidths of some op amps. Aspects of the present disclosure recognize that, by monitoring the frequency at which an op amp oscillates, the compensation capacitor can be calibrated or tuned to cause the op amp to operate with a desired bandwidth.

Various aspects relate generally to frequency compensation techniques for op amps, and more particularly, to dynamically calibrating the capacitance of a compensation capacitor based on the frequency at which an op amp oscillates. In some aspects, a multi-stage amplifier may include a differential input stage, a high gain stage, and a frequency compensation controller configured to operate the multi-stage op amp in a normal mode or a calibration mode. The differential input stage includes a pair of input terminals and a pair of output terminals configured to provide a differential output voltage based on a voltage difference detected across the input terminals of the differential input stage. The high gain stage includes a pair of input terminals, coupled to respective output terminals of the differential input stage, and a pair of output terminals configured to provide an amplified output voltage based on the differential output voltage produced by the differential input stage.

In some implementations, the multi-stage amplifier may further include first and second compensation capacitors that are switchably coupled between the outputs of the differential input stage and the outputs of the high gain stage based on whether the multi-stage op amp operates in the normal mode or the calibration mode. More specifically, when operating in the normal mode, the first compensation capacitor is coupled between a first output of the high gain stage and a first output of the differential input stage while the second compensation capacitor is coupled to between a second output of the high gain stage and a second output of the differential input stage. On the other hand, when operating in the calibration mode, the first compensation capacitor is coupled between the first output of the high gain stage and the second output of the differential input stage while the second compensation capacitor is coupled between the second output of the high gain stage and the first output of the differential input stage.

In the calibration mode, the cross-coupling of the feedback paths (via the compensation capacitors) causes the output voltage of the multi-stage op-amp to oscillate. In some aspects, the frequency compensation controller may calibrate the op amp while operating in the calibration mode to achieve a desired frequency of oscillation in the output voltage. For example, the frequency compensation controller may adjust one or more parameters of the multi-stage op amp so that the output voltage oscillates at a predetermined frequency known to result in stable operation. In some implementations, the frequency compensation controller may calibrate the op amp by adjusting the capacitances of the first and second compensation capacitors. In some other implementations, the frequency compensation controller may calibrate the op amp by adjusting a current through the op amp. After the multi-stage op amp is calibrated, the frequency compensation controller may reconfigure the op amp to operate in the normal mode.

Particular implementations of the subject matter described in this disclosure can be implemented to realize one or more of the following potential advantages. In contrast with existing frequency compensation techniques, which often result in overcompensation, aspects of the present disclosure may optimize the bandwidth of an op amp for stable operation based on a measured frequency response of the op amp. For example, by configuring an op-amp in the calibration mode, the frequency compensation controller causes the op amp to produce an output voltage that oscillates at a frequency associated with its bandwidth. Thus, the frequency compensation controller can dynamically tune the frequency response of the op amp (such as by adjusting the capacitances of the compensation capacitors or by adjusting the current through the op amp) to achieve a desired bandwidth while ensuring the stability of the op amp.

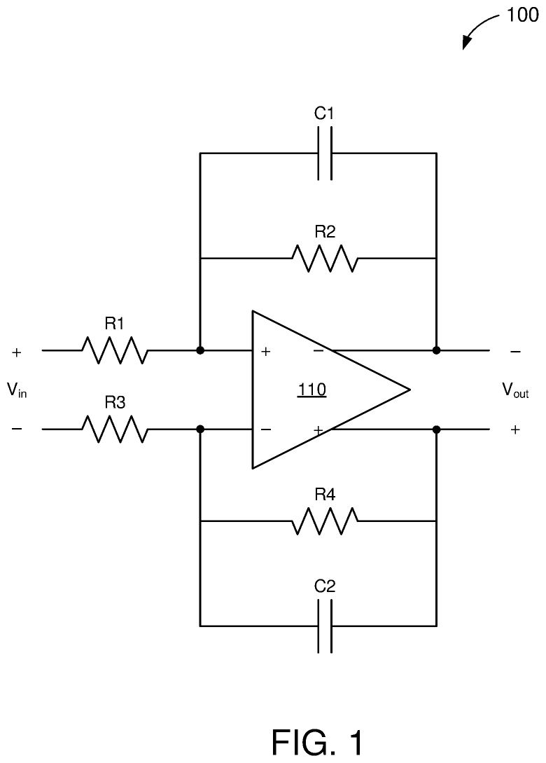

FIG. 1 shows an example amplifier circuit 100 based on an op amp 110. In some implementations, the op amp 110 may have a pair of differential input terminals, including an inverting (−) input and a non-inverting (+) input, as well as a pair of output terminals, including a positive (+) output and a negative (−) output. Each input terminal of the op amp 110 is coupled to a respective resistor (R1 or R3) and the output terminals of the op amp 110 may be coupled to a load (not shown for simplicity).

In the example of FIG. 1, the op amp 110 is depicted in a closed loop configuration. For example, the negative output of the op amp 110 is coupled to the non-inverting input via a feedback path that includes a resistor (R2), and the positive output of the op amp 110 is coupled to the inverting input via a feedback path that includes a resistor (R4). In some implementations, the amplifier circuit 110 may receive a differential input signal or voltage (Vᵢₙ) and produce a differential output signal or voltage (Vₒᵤₜ) based on the input signal Vᵢₙ. More specifically, the op amp 110 is configured to produce the voltage differential Vₒᵤₜ across its output terminals by amplifying the difference between the voltages across its input terminals. The closed-loop gain of the op amp 110 is proportional to the resistances of R1-R4, such that

$$\frac{{V}_{out}}{{V}_{in}} = - \frac{R 2}{R 1} = - \frac{R 4}{R 3} .$$

Capacitances in the load and parasitic capacitances in the op amp 110 introduce phase shifts between the input signal Vᵢₙ and output signal Vₒᵤₜ (characterized by “poles” in the frequency response curve). More specifically, each pole introduces a 90° phase shift between the signals Vᵢₙ and Vₒᵤₜ, and results in a 20 dB/decade increase in the slope of the frequency response curve (representing an increase in the rate at which the gain of the op amp 110 falls). As a result, the op amp 110 will oscillate if the frequency of the input signal is greater than a second pole on the frequency response curve (due to a 180° phase shift between Vᵢₙ and Vₒᵤₜ). Frequency compensation techniques may be used to prevent the op amp 110 from oscillating, resulting in a “stable” op amp.

In the example of FIG. 1, a respective capacitor (C1 or C2) is coupled to each of the feedback loops between the output terminals of the input terminals of the op amp 110. More specifically, the capacitor C1 is coupled in parallel with the resistor R2 and the capacitor C2 is coupled in parallel with the resistor R4. The capacitors C1 and C2 (also referred to as “compensation capacitors”) introduce additional capacitance to the first pole of the op amp 110. As such, the capacitors C1 and C2 can be used to increase the frequency separation between the first and second poles in the frequency response curve so that the op amp 110 reaches unity gain (0 dB) before Vᵢₙ and Vₒᵤₜ are shifted 180° out of phase. In other words, the capacitors C1 and C2 can be configured to ensure stable operation of the op amp 110.

In existing frequency compensation techniques, compensation capacitors are often designed to ensure stable operation at the process corners. For example, the capacitances of C1 and C2 may be configured so that the op amp 110 has a phase margin of 45° or 60° (equal to 180° minus the phase at unity gain) under extreme or worst-case process variations. However, due to process variations, the resulting phase margin may be significantly larger when the same capacitances for C1 and C2 are applied to some op amps that are manufactured using the same process (such as any op amps that are not subject to the worst-case process variations). As such, existing frequency compensation techniques often result in overcompensation, which may unnecessarily reduce the bandwidths of some op amps.

In some aspects, the compensation capacitors C1 and C2 may be dynamically tuned or calibrated based on the frequency response of the op amp 110. More specifically, the capacitances of C1 and C2 may be configured to ensure that the op amp 110 is stable while maintaining a target bandwidth. For example, the target bandwidth may be associated with a 45° phase margin at the process corners. However, by dynamically calibrating the compensation capacitors C1 and C2 per op amp, some op amps may have different values of C1 and C2 than some other op amps manufactured using the same process. In other words, aspects of the present disclosure may maintain a consistent bandwidth (rather than consistent compensation capacitor values) for all op amps manufactured using the same process, regardless of process variations.

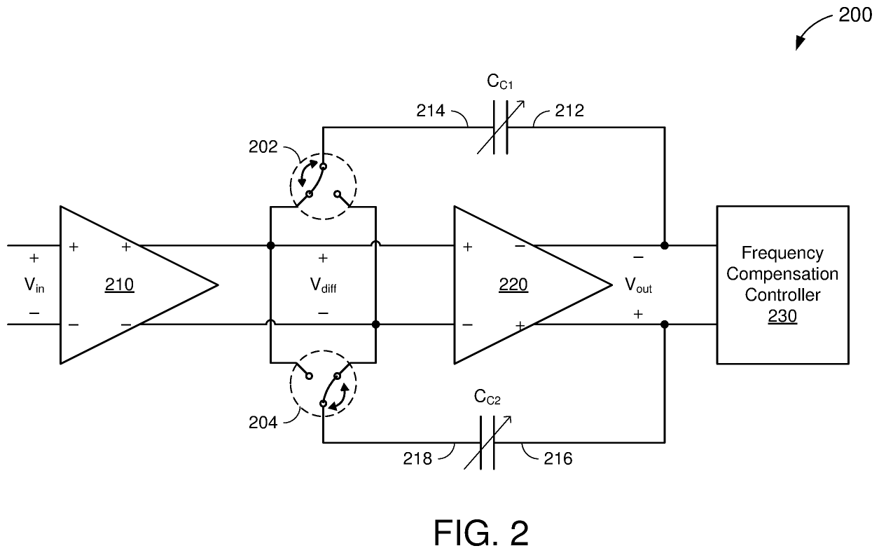

FIG. 2 shows an example multi-stage op amp 200 capable of dynamic frequency compensation, according to some implementations. In some implementations, the op amp 200 may be one example of the amplifier circuit 100 of FIG. 1. More specifically, the op amp 200 is configured to receive a differential input signal or voltage (Vᵢₙ) and produce a differential output signal or voltage (Vₒᵤₜ) based, at least in part, on the input signal Vᵢₙ.

The multi-stage op amp 200 includes a differential input stage 210 a high gain stage 220, and a frequency compensation controller 230. The differential input stage 210 has a non-inverting (+) and an inverting (−) input terminals as well as positive (+) and negative (−) output terminals. The input terminals of the differential input stage 210 are configured to receive the input signal Vᵢₙ, and the output terminals of the differential input stage 210 are configured to provide a differential voltage (V_{diff}). More specifically, the differential input stage 210 is configured to produce the differential voltage V_{diff} by amplifying the difference between the voltages across its input terminals by a first gain factor (A₁).

The high gain stage 220 has non-inverting (+) and inverting (−) input terminals as well as positive (+) and negative (−) output terminals. The non-inverting and inverting terminals of the high gain stage 220 are coupled to the positive and negative output terminals, respectively, of the differential input stage 210. The output terminals of the high gain stage 220 are configured to provide the output signal Vₒᵤₜ. More specifically, the high gain stage 220 is configured to produce the output signal Vₒᵤₜ by amplifying the differential voltage V_{diff}, received across its input terminals, by a second gain factor (A₂). In some implementations, the second gain factor A₂ may be higher than the first gain factor A₁ (A₂>A₁).

In some implementations, the multi-stage op amp 200 may further include a pair of compensation capacitors (C_{C1} and C_{C2}) switchably coupled between the output terminals of the differential input stage 210 and the output terminals of the high gain stage 220. More specifically, the capacitor C_{C1} has a first terminal 212 coupled to the negative output terminal of the high gain stage 220 and a second terminal 214 coupled, via a switch 202, to one of the output terminals of the differential input stage 210. Similarly, the capacitor C_{C2} has a first terminal 216 coupled to the positive output terminal of the high gain stage 220 and a second terminal 218 coupled, via a switch 204, to one of the output terminals of the differential input stage 210.

In some aspects, the frequency compensation controller 230 may control the switches 202 and 204. For example, the frequency compensation controller 230 may operate the multi-stage op amp 200 in either a “normal” mode or a “configuration” mode. When the op amp 200 operates in the normal mode, the switches 202 and 204 are configured as shown in FIG. 2. More specifically, the switch 202 couples the second terminal 214 of the capacitor C_{C1} to the positive output terminal of the differential input stage 210 and the switch 204 couples the second terminal 218 of the capacitor C_{C2} to the negative output terminal of the differential input stage 210. In other words, the high gain stage 220 is configured with negative feedback. As a result, the voltage of the output signal Vₒᵤₜ follows or tracks the voltage of the input signal Vᵢₙ.

When the op amp 200 operates in the calibration mode, the polarities of the switches 202 and 204 are reversed. In other words, the switch 202 couples the second terminal 214 of the capacitor C_{C1} to the negative output terminal of the differential input stage 210 and the switch 204 couples the second terminal 218 of the capacitor C_{C2} to the positive output terminal of the differential input stage 210. In other words, the high gain stage 220 is configured with positive feedback. As a result, the voltage of the output signal Vₒᵤₜ oscillates. Aspects of the present disclosure recognize that the frequency at which Vₒᵤₜ oscillates is associated with the bandwidth of the multi-stage op amp 200.

In some aspects, the frequency compensation controller 230 may calibrate the op amp 200 to oscillate at a predetermined frequency while operating in the calibration mode. In some implementations, the predetermined frequency may be associated with a target bandwidth that is known to result in stable operation of the op amp 200. For example, the frequency compensation controller 230 may monitor the output signal Vₒᵤₜ, while adjusting one or more parameters of the op amp 200, to achieve the desired frequency of oscillation. In some implementations, the frequency compensation controller 230 may adjust the capacitances of the compensation capacitors C_{C1} and C_{C2} to achieve the desired frequency of oscillation. In some other implementations, the frequency compensation controller 230 may adjust the current through the op amp 200 to achieve the desired frequency of oscillation.

After completing the op amp calibration (such as when Vₒᵤₜ oscillates at a desired frequency), the frequency compensation controller 230 may configure (or reconfigure) the multi-stage op amp 200 to operate in the normal mode. Any changes made to the capacitances of the compensation capacitors C_{C1} and C_{C2} or current through the op amp 200, while in the calibration mode, are retained when the op amp 200 resumes operation in the normal mode.

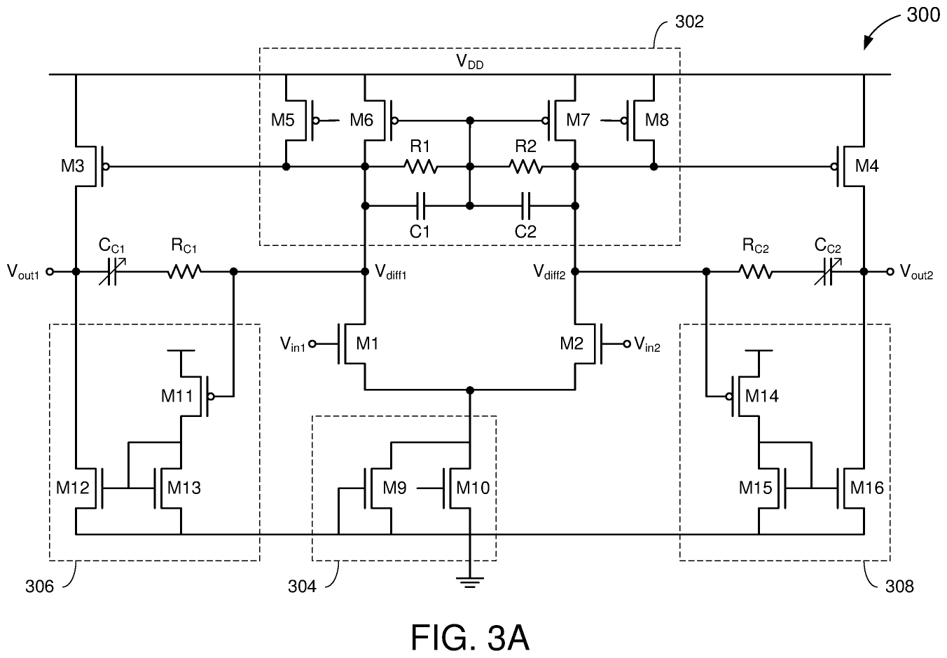

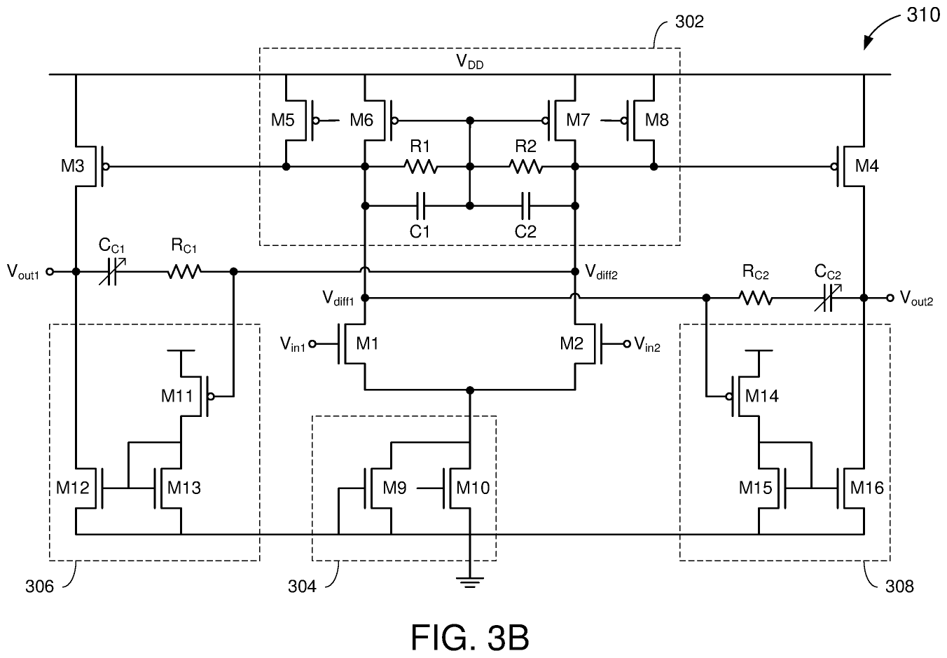

FIG. 3A shows a circuit diagram of an example multi-stage op amp 300 configured in a normal operating mode. In some implementations, the multi-stage op amp 300 may be one example of the op amp 200 of FIG. 2. More specifically, the op amp 300 may be a circuit configuration of the op amp 200 when operating in the normal mode. The op amp 300 is configured to receive a differential input signal or voltage (Vᵢₙ₁−Vᵢₙ₂) and produce a differential output signal or voltage (Vₒᵤₜ₁−Vₒᵤₜ₂) based, at least in part, on the input signal. With reference for example to FIG. 2, the differential input signal Vᵢₙ₁−Vᵢₙ₂ may be one example of the input signal Vᵢₙ and the differential output signal Vₒᵤₜ₁−Vₒᵤₜ₂ may be one example of the output signal Vₒᵤₜ.

The multi-stage op amp 300 is shown to include N-type metal-oxide-semiconductor (NMOS) field-effect transistors M1 and M2, P-type metal-oxide-semiconductor (PMOS) field-effect transistors M3 and M4, and current sources 302-308. More specifically, the current source 302 includes PMOS transistors M5-M8, resistors R1 and R2, and capacitors C1 and C2; the current source 304 includes NMOS transistors M9 and M10; the current source 306 includes a PMOS transistor M11 and NMOs transistors M11-M13; and the current source 308 includes a PMOS transistor M14 and NMOS transistors M15-M16. In some other implementations, one or more PMOS transistors may be substituted for NMOS transistors. In some other implementations, one or more NMOS transistors may be substituted for PMOS transistors.

The NMOS transistors M1 and M2, and current sources 302 and 304, collectively form a differential input stage of the multi-stage op amp 300 (such as the differential input stage 210 of FIG. 2). More specifically, the differential input stage amplifies the difference between the input voltages Vᵢₙ₁ and Vᵢₙ₂ to produce a differential voltage V_{diff1}−V_{diff2}. With reference for example to FIG. 2, the differential voltage V_{diff1}−V_{diff2} may be one example of the differential voltage V_{diff}. The PMOS transistors M3 and M4, and current sources 306 and 308, collectively form a high gain stage of the multi-stage op amp 300. More specifically, the high gain stage amplifies the differential voltages V_{diff1} and V_{diff2} to produce the output voltages Vₒᵤₜ₁ and Vₒᵤₜ₂.

In the example of FIG. 3A, the multi-stage op amp 300 includes compensation capacitors C_{C1} and C_{C2}, and resistors R_{C1} and R_{C2}, coupled in negative feedback between the outputs Vₒᵤₜ₁ and Vₒᵤₜ₂ of the high gain stage and the outputs V_{diff1} and V_{diff2} of the differential input stage. More specifically, the compensation capacitor C_{C1} is coupled, in series with the resistor R_{C1}, between Vₒᵤₜ₁ and V_{diff1}. In some implementations, the compensation capacitor C_{C1} and the resistor R_{C1} may be coupled to V_{diff1} via a switch (not shown for simplicity). On the other hand, the compensation capacitor C_{C2} is coupled, in series with the resistor R_{C2}, between V_{diff2} and Vₒᵤₜ₂. In some implementations, the compensation capacitor C_{C2} and the resistor R_{C2} may be coupled to V_{diff2} via a switch (not shown for simplicity). In the configuration depicted in FIG. 3A, the output voltages Vₒᵤₜ₁ and Vₒᵤₜ₂ follow or track the input voltage Vᵢₙ₁ and Vᵢₙ₂.

FIG. 3B shows a circuit diagram of an example multi-stage op amp 310 configured in a calibration mode, according to some implementations. In some implementations, the multi-stage op amp 310 may be one example of the op amp 200 of FIG. 2. More specifically, the op amp 310 may be a circuit configuration of the op amp 200 when operating in the calibration mode. With reference for example to FIG. 3A, the op amp 310 includes the same circuit components as the op amp 300. However, the interconnections between some of the circuit components are modified in the op amp 310 compared to the op amp 300. In some implementations, the modifications may be managed by a controller (such as the frequency compensation controller 230 of FIG. 2).

In the example of FIG. 3B, the compensation capacitors C_{C1} and C_{C2} and resistors R_{C1} and R_{C2} are coupled in positive feedback between the outputs Vₒᵤₜ₁ and Vₒᵤₜ₂ of the high gain stage and the outputs V_{diff1} and V_{diff2} of the differential input stage. More specifically, the compensation capacitor C_{C1} is coupled, in series with the resistor R_{C1}, between Vₒᵤₜ₁ and V_{diff2}. In some implementations, the compensation capacitor C_{C2} and resistor R_{C1} may be coupled to V_{diff2} via a switch (not shown for simplicity). On the other hand, the compensation capacitor C_{C2} is coupled, in series with the resistor R_{C2}, between V_{diff2} and Vₒᵤₜ₂. In some implementations, the compensation capacitor C_{C2} and the resistor R_{C2} may be coupled to V_{diff2} via a switch (not shown for simplicity). In the configuration depicted in FIG. 3B, the output voltages Vₒᵤₜ₁ and Vₒᵤₜ₂ oscillate at a frequency associated with the bandwidth of the op amp 310.

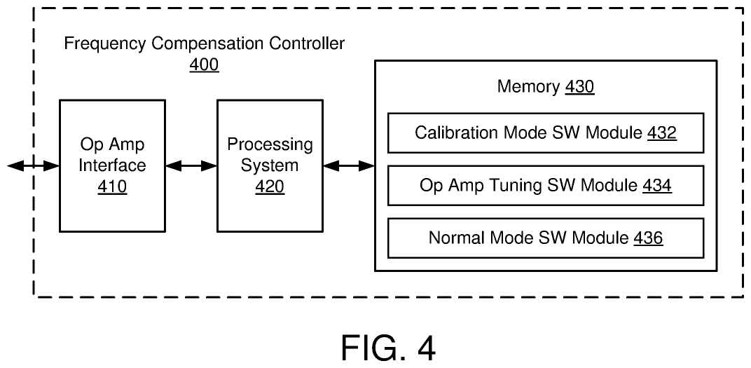

FIG. 4 shows a block diagram of an example frequency compensation controller 400, according to some implementations. In some implementations, the frequency compensation controller 400 may be one example of the frequency compensation controller 230 of FIG. 2.

The frequency compensation controller 400 includes an op amp interface 410, a processing system 420, and a memory 430. The op amp interface 410 is configured to communicate with one or more components of a multi-stage op amp (such as the multi-stage op amp 200 of FIG. 2). In some implementations, the op amp interface 410 may receive differential voltage signals output by the multi-stage op amp (such as the output signal Vₒᵤₜ of FIG. 2). In some implementations, the op amp interface 410 may provide control signals to one or more compensation capacitors associated with the multi-stage op amp (such as the compensation capacitors C_{C1} and C_{C2}), for example, to control or adjust the capacitances of the compensation capacitors.

The memory 430 may include a non-transitory computer-readable medium (including one or more nonvolatile memory elements, such as EPROM, EEPROM, Flash memory, a hard drive, and the like) that may store at least the following software (SW) modules:
a calibration mode SW module 432 to configure the multi-stage op amp to operate in a calibration mode so that the multi-stage op amp produces a first output voltage that oscillates in response to an input voltage received by the multi-stage op amp;
an op amp tuning SW module 434 to tune a capacitance or current associated with the multi-stage op amp so that the first output voltage oscillates at a target frequency when the multi-stage op amp is configured to operate in the calibration mode; and
a normal mode SW module 436 to configure the multi-stage op amp to operate in a normal mode so that the multi-stage op amp produces a second output voltage that tracks the input voltage based on the tuned capacitance or current.
   Each software module includes instructions that, when executed by the processing system 420, causes the frequency compensation controller 400 to perform the corresponding functions.

The processing system 420 may include any suitable one or more processors capable of executing scripts or instructions of one or more software programs stored in the frequency compensation controller 400 (such as in the memory 430). For example, the processing system 420 may execute the calibration mode SW module 432 to configure the multi-stage op amp to operate in the calibration mode so that the multi-stage op amp produces a first output voltage that oscillates in response to an input voltage received by the multi-stage op amp. The processing system 420 may execute the op amp tuning SW module 434 to tune a capacitance or current associated with the multi-stage op amp so that the first output voltage oscillates at a target frequency when the multi-stage op amp is configured to operate in the calibration mode. The processor 420 may further execute the normal mode SW module 436 to configure the multi-stage op amp to operate in the normal mode so that the multi-stage op amp produces a second output voltage that tracks the input voltage based on the tuned capacitance or current.

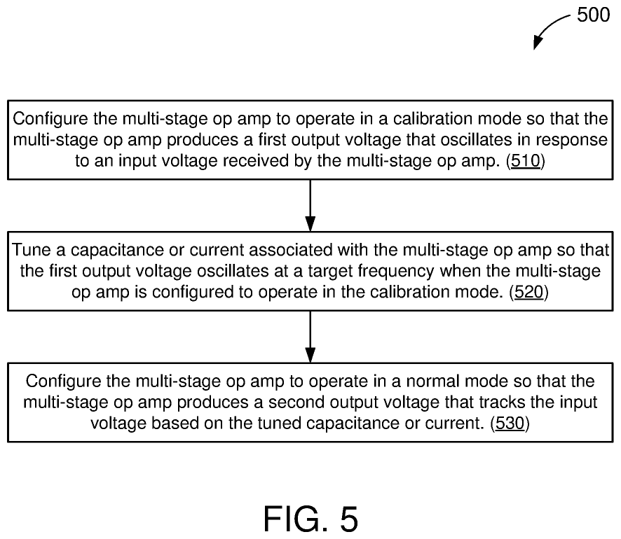

FIG. 5 shows an illustrative flowchart depicting an example operation 500 for tuning a multi-stage op amp, according to some implementations. In some implementations, the example operation 500 may be performed by a controller for a multi-stage op amp such as any of the frequency compensation controllers 230 or 400 of FIGS. 2 and 4, respectively. With reference to FIG. 2, the multi-stage op amp may be one example of the multi-stage op amp 200.

The controller configures the multi-stage op amp to operate in a calibration mode so that the multi-stage op amp produces a first output voltage that oscillates in response to an input voltage received by the multi-stage op amp (510). The controller tunes a capacitance or current associated with the multi-stage op amp so that the first output voltage oscillates at a target frequency when the multi-stage op amp is configured to operate in the calibration mode (520). The controller configures the multi-stage op amp to operate in a normal mode so that the multi-stage op amp produces a second output voltage that tracks the input voltage based on the tuned capacitance or current (530).

In some aspects, the multi-stage op amp may include a first amplifier stage configured to receive the input voltage via a pair of first and second input terminals and produce an intermediate voltage between a pair of first and second output terminals based on a voltage difference between the first and second input terminals; and a second amplifier stage configured to receive the intermediate voltage via a pair of third and fourth input terminals and produce the first output voltage or the second output voltage between a pair of second and third output terminals based on whether the multi-stage op amp is configured to operate in the calibration mode or the normal mode.

In some implementations, the multi-stage op amp may further include a first compensation capacitor having a first terminal coupled to the third output terminal of the second amplifier stage and a second terminal switchably coupled to one of the first or second output terminals of the first amplifier stage based on whether the multi-stage op amp is configured to operate in the calibration mode or the normal mode; and a second compensation capacitor having a first terminal coupled to the fourth output terminal of the second amplifier stage and a second terminal switchably coupled to one of the first or second output terminals of the first amplifier stage based on whether the multi-stage op amp is configured to operate in the calibration mode or the normal mode. In some implementations, the tuning of the capacitance associated with the multi-stage op amp may include adjusting capacitances of the first and second compensation capacitors.

In some implementations, the configuring of the multi-stage op amp to operate in the calibration mode may include coupling the second terminal of the first compensation capacitor to the second output terminal of the first amplifier stage and coupling the second terminal of the second compensation capacitor to the first output terminal of the first amplifier stage. In some implementations, the configuring of the multi-stage op amp to operate in the normal mode may include coupling the second terminal of the first compensation capacitor to the first output terminal of the first amplifier stage; and coupling the second terminal of the second compensation capacitor to the second output terminal of the first amplifier stage.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the disclosure.

The methods, sequences or algorithms described in connection with the aspects disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor.

In the foregoing specification, embodiments have been described with reference to specific examples thereof. It will, however, be evident that various modifications and changes may be made thereto without departing from the broader scope of the disclosure as set forth in the appended claims. The specification and drawings are, accordingly, to be regarded in an illustrative sense rather than a restrictive sense.

What is claimed is:

1. A multi-stage operational amplifier (op amp), comprising:
a first amplifier stage having a pair of first and second input terminals and a pair of first and second output terminals, the first amplifier stage being configured to produce a first differential voltage across the first and second output terminals based on a voltage difference between the first and second input terminals;
a second amplifier stage having a pair of third and fourth output terminals and a pair of third and fourth input terminals coupled to the first and second output terminals, respectively, of the first amplifier stage, the second amplifier stage being configured to produce a second differential voltage between the third and fourth output terminals based on the first differential voltage;
a controller configured to operate the multi-stage op amp in a normal mode or a calibration mode;
a first compensation capacitor having a first terminal coupled to the third output terminal of the second amplifier stage and a second terminal switchably coupled to one of the first or second output terminals of the first amplifier stage based on whether the multi-stage op amp operates in the normal mode or the calibration mode; and
a second compensation capacitor having a first terminal coupled to the fourth output terminal of the second amplifier stage and a second terminal switchably coupled to one of the first or second output terminals of the first amplifier stage based on whether the multi-stage op amp operates in the normal mode or the calibration mode.

2. The multi-stage op amp of claim 1, wherein the second terminals of the first and second compensation capacitors are coupled to the first and second output terminals, respectively, when the multi-stage op amp operates in the normal mode, and coupled to the second and first output terminals, respectively, when the multi-stage op amp operates in the calibration mode.

3. The multi-stage op amp of claim 2, wherein the controller is further configured to adjust capacitances of the first and second compensation capacitors based on the second differential voltage when operating the multi-stage op amp in the calibration mode.

4. The multi-stage op amp of claim 3, wherein the capacitances of the first and second compensation capacitors are adjusted so that the second differential voltage oscillates at a target frequency when the multi-stage op amp operates in the calibration mode.

5. The multi-stage op amp of claim 3, wherein the controller is configured to operate the multi-stage op amp in the normal mode responsive to adjusting the capacitances of the first and second compensation capacitors while operating the multi-stage op amp in the calibration mode.

6. The multi-stage op amp of claim 2, wherein the controller is further configured to adjust a current through the multi-stage op amp based on the second differential voltage when operating the multi-stage op amp in the calibration mode.

7. The multi-stage op amp of claim 6, wherein the current is adjusted so that the second differential voltage oscillates at a target frequency when the multi-stage op amp operates in the calibration mode.

8. The multi-stage op amp of claim 6, wherein the controller is further configured to operate the multi-stage op amp in the normal mode responsive to adjusting the current through the multi-stage op amp while operating the multi-stage op amp in the calibration mode.

9. A method performed by a controller for a multi-stage operational amplifier (op amp), comprising:
configuring the multi-stage op amp to operate in a calibration mode so that the multi-stage op amp produces a first output voltage that oscillates in response to an input voltage received by the multi-stage op amp;
tuning a capacitance or current associated with the multi-stage op amp so that the first output voltage oscillates at a target frequency when the multi-stage op amp is configured to operate in the calibration mode; and
configuring the multi-stage op amp to operate in a normal mode so that the multi-stage op amp produces a second output voltage that tracks the input voltage based on the tuned capacitance or current.

10. The method of claim 9, wherein the multi-stage op amp comprises:
a first amplifier stage configured to receive the input voltage via a pair of first and second input terminals and produce an intermediate voltage between a pair of first and second output terminals based on a voltage difference between the first and second input terminals; and
a second amplifier stage configured to receive the intermediate voltage via a pair of third and fourth input terminals and produce the first output voltage or the second output voltage between a pair of second and third output terminals based on whether the multi-stage op amp is configured to operate in the calibration mode or the normal mode.

11. The method of claim 10, wherein the multi-stage op amp further comprises:
a first compensation capacitor having a first terminal coupled to the third output terminal of the second amplifier stage and a second terminal switchably coupled to one of the first or second output terminals of the first amplifier stage based on whether the multi-stage op amp is configured to operate in the calibration mode or the normal mode; and
a second compensation capacitor having a first terminal coupled to the fourth output terminal of the second amplifier stage and a second terminal switchably coupled to one of the first or second output terminals of the first amplifier stage based on whether the multi-stage op amp is configured to operate in the calibration mode or the normal mode.

12. The method of claim 11, wherein the configuring of the multi-stage op amp to operate in the calibration mode comprises:
coupling the second terminal of the first compensation capacitor to the second output terminal of the first amplifier stage; and
coupling the second terminal of the second compensation capacitor to the first output terminal of the first amplifier stage.

13. The method of claim 11, wherein the configuring of the multi-stage op amp to operate in the normal mode comprises:
coupling the second terminal of the first compensation capacitor to the first output terminal of the first amplifier stage; and
coupling the second terminal of the second compensation capacitor to the second output terminal of the first amplifier stage.

14. The method of claim 11, wherein the tuning of the capacitance associated with the multi-stage op amp comprises adjusting capacitances of the first and second compensation capacitors.

15. A controller for a multi-stage operational amplifier (op amp), comprising:
a processing system; and
a memory storing instructions that, when executed by the processing system, causes the controller to:
configure the multi-stage op amp to operate in a calibration mode so that the multi-stage op amp produces a first output voltage that oscillates in response to an input voltage received by the multi-stage op amp;
tune a capacitance or current associated with the multi-stage op amp so that the first output voltage oscillates at a target frequency when the multi-stage op amp is configured to operate in the calibration mode; and
configure the multi-stage op amp to operate in a normal mode so that the multi-stage op amp produces a second output voltage that tracks the input voltage based on the tuned capacitance or current.

16. The controller of claim 15, wherein the multi-stage op amp comprises:
a first amplifier stage configured to receive the input voltage via a pair of first and second input terminals and produce an intermediate voltage between a pair of first and second output terminals based on a voltage difference between the first and second input terminals; and
a second amplifier stage configured to receive the intermediate voltage via a pair of third and fourth input terminals and produce the first output voltage or the second output voltage between a pair of second and third output terminals based on whether the multi-stage op amp is configured to operate in the calibration mode or the normal mode.

17. The controller of claim 16, wherein the multi-stage op amp further comprises:
a first compensation capacitor having a first terminal coupled to the third output terminal of the second amplifier stage and a second terminal switchably coupled to one of the first or second output terminals of the first amplifier stage based on whether the multi-stage op amp is configured to operate in the calibration mode or the normal mode; and
a second compensation capacitor having a first terminal coupled to the fourth output terminal of the second amplifier stage and a second terminal switchably coupled to one of the first or second output terminals of the first amplifier stage based on whether the multi-stage op amp is configured to operate in the calibration mode or the normal mode.

18. The controller of claim 17, wherein the configuring of the multi-stage op amp to operate in the calibration mode comprises:
coupling the second terminal of the first compensation capacitor to the second output terminal of the first amplifier stage; and
coupling the second terminal of the second compensation capacitor to the first output terminal of the first amplifier stage.

19. The controller of claim 17, wherein the configuring of the multi-stage op amp to operate in the normal mode comprises:
coupling the second terminal of the first compensation capacitor to the first output terminal of the first amplifier stage; and
coupling the second terminal of the second compensation capacitor to the second output terminal of the first amplifier stage.

20. The controller of claim 17, wherein the tuning of the capacitance associated with the multi-stage op amp comprises adjusting capacitances of the first and second compensation capacitors.
